(19) United States
(12) Patent Application Publication
(10) Pub. No.: US 2008/0278897 A1
(43) Pub. Date: Nov. 13, 2008

(54) PORTABLE ELECTRONIC DEVICE

(75) Inventors: Jin-Soo Kim, Suwon-si (KR); Jae-Chul Jin, Suwon-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/118,196

(22) Filed: May 9, 2008

(30) Foreign Application Priority Data
May 10, 2007 (KR) 10-2007-0045581

(51) Int. Cl. H05K 5/02

(52) U.S. Cl. 361/681

(57) ABSTRACT

Disclosed is a portable electronic device adapted to be used and watched conveniently. The device includes a first housing having a keypad, a second housing having a display device; and a connection unit to rotatably couple the first and second housings so that the second housing can be rotated about a first hinge axis relative to the first housing and then can be fixed at a specific angle of rotation.

### CROSS REFERENCE TO RELATED APPLICATION

This application claims priority from and the benefit of Korean Patent Application No. 10-2007-0045581, filed on May 10, 2007, which is hereby incorporated by reference for all purposes as if fully set forth herein.

### BACKGROUND OF THE INVENTION

1. Field of the Invention

The present invention relates to a portable electronic device, such as a DMB phone, a game phone, a chatting phone, a camera phone, an MP3 phone, a cellular phone, a PCS, a Personal Digital Assistant (PDA), and a Hand Held Phone (HHP), and more particularly, to a portable electronic device adapted to be used and watched conveniently.

2. Discussion of the Background

A portable electronic device refers to an electronic device carried by a user for wireless communication with a desired person. Portable electronic devices are becoming smaller, slimmer, easier to grip, and lighter for better portability. Portable electronic devices are also evolving to incorporate more functions, especially multimedia-related functions. Future portable electronic devices will most likely be smaller and lighter, as well as adapted for more functions and purposes, including various multimedia and Internet environments. Today, portable electronic devices are used by people from every walk of life all around the globe, and are even regarded as daily necessities by some people.

Conventional portable electronic devices may be classified as bar-type devices, flip-type devices, or folder-type devices according to their appearance. Bar-type devices have a single bar-shaped housing. Flip-type devices have a bar-shaped housing and a flip part rotatably connected to the housing by a hinge device. Folder-type devices have a single bar-shaped housing and a folder connected to the housing by a hinge device so that the folder rotates to be folded/unfolded.

However, conventional portable electronic devices may rely on a separate cradle to enable users to conveniently watch information displayed by the display device. This is uneconomical from the users' point of view because users may not be able to conveniently watch information displayed by the display unit unless it is placed at an angle. If no separate cradle is provided, a user may have to manually tilt the body of the device and watch the screen of the display unit, which may otherwise be inconvenient to watch, particularly when placed on a table.

When conventional portable electronic devices are used for purposes other than watching TV, e.g. for games, users may need to hold them with one hand and operate buttons with the other hand in an inconvenient manner.

### SUMMARY OF THE INVENTION

The present invention provides a portable electronic device having a display unit adapted to be positioned at an angle so that the user may conveniently watch TV programs and moving pictures.

The present invention also provides a portable electronic device having a display unit that is mounted in a recess of a housing and adapted to rotate to be positioned at an angle so that a user may efficiently use the device and conveniently watch TV programs and moving pictures.

Additional features of the invention will be set forth in the description which follows, and in part will be apparent from the description, or may be learned by practice of the invention.

The present invention discloses a bar-type portable electronic device including a first housing having a keypad, a second housing having a display device, and a connection unit to rotatably couple the first and second housings so that the second housing can be rotated about a first hinge axis relative to the first housing and can be fixed at a specific angle of rotation.

The present invention also discloses a portable electronic device including a first housing having a keypad and a second housing having a display device. The second housing is adapted to rotate about a first hinge axis so that the display device is positioned at the center of the first housing and then to rotate about a second hinge axis extending in a direction perpendicular to the first hinge axis to be cradled at an angle. The portable electronic device further includes a connection unit to provide the first and second hinge axes and to connect the first and second housings so as to rotate the second housing about the first and second hinge axes.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a perspective view of a flat state of a portable electronic device according to a first exemplary embodiment of the present invention.

FIG. 2 is a perspective view of an inclined state of the portable electronic device according to the first exemplary embodiment of the present invention.

FIG. 3 is an exploded perspective view showing the components of a portable electronic device according to a second exemplary embodiment of the present invention.

FIG. 4 is a perspective view of the portable electronic device according to the second exemplary embodiment of the present invention, before it is assembled.

FIG. 5 is a perspective view of the portable electronic device according to the second exemplary embodiment of the present invention, before the second case of the connection unit is coupled to the device.

FIG. 6 is a perspective view of the portable electronic device according to the second exemplary embodiment of the present invention, before the first case of the second housing is coupled to the device.

FIG. 7 is a perspective view of the portable electronic device according to the second exemplary embodiment of the present invention, after the device is assembled.

FIG. 8 is a top view of the portable electronic device according to the second embodiment of the present invention, before the device is rotated.

FIG. 9 is a perspective view of the portable electronic device according to the second exemplary embodiment of the present invention, when the second housing is rotating.

FIG. 10 is a top view of the portable electronic device according to the second exemplary embodiment of the present invention, when the second housing is rotating.

FIG. 11 is a perspective view of the portable electronic device according to the second exemplary embodiment of the present invention, after the second housing is rotated.

FIG. 12 is a top view of the portable electronic device according to the second exemplary embodiment of the present invention, after the second housing is rotated.

FIG. 13 is a perspective view of the portable electronic device according to the second exemplary embodiment of the present invention, when the second housing and the connection unit are cradled at an angle.

FIG. 14 is a partially-broken perspective view of the portable electronic device according to the second exemplary embodiment of the present invention, when the second housing and the connection unit are cradled at an angle.

FIG. 15 is a perspective view magnifying part A shown in FIG. 14.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. Like reference numerals in the drawings denote like elements.

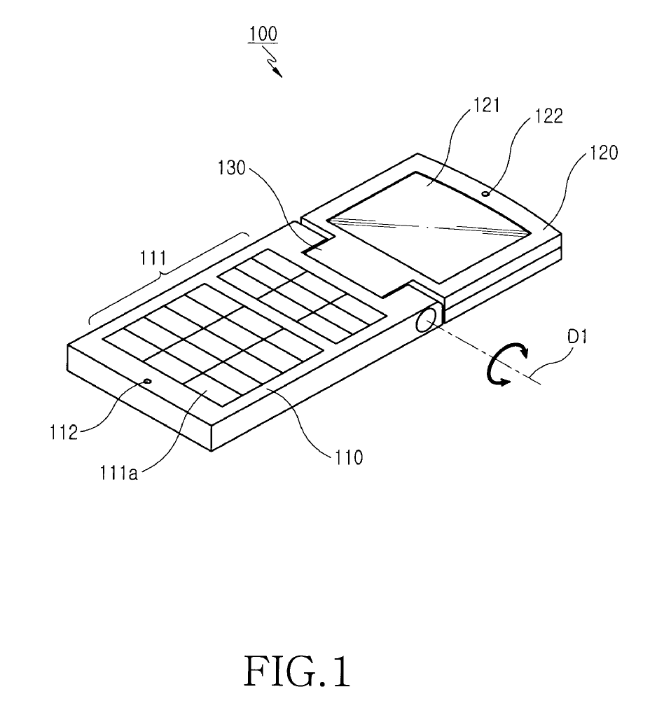

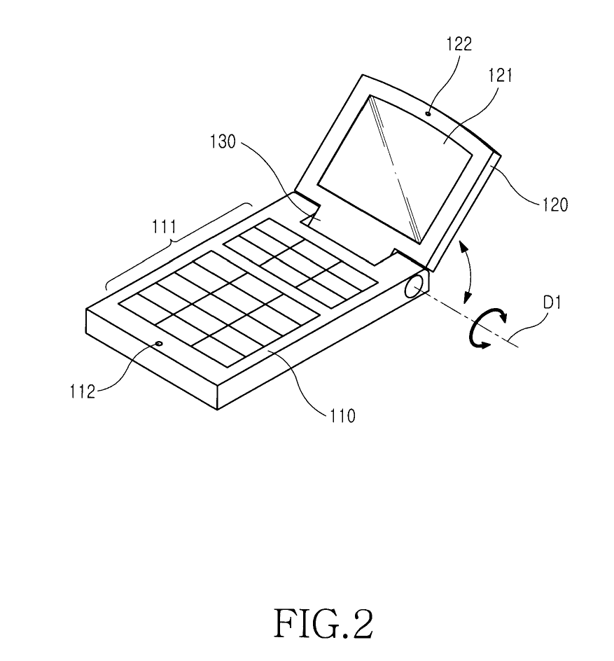

As shown in FIG. 1 and FIG. 2, a portable electronic device 100 according to a first exemplary embodiment of the present invention includes a first housing 110, a second housing 120, and a connection unit 130. The first housing 110 includes a keypad 111 having a number of keys 11a arranged thereon, and a microphone device 112. The second housing 120 includes a display device 121 and a speaker device 122. The connection unit 130 rotatably connects the first and second housings 110 and 120 so that the second housing 120 can be rotated about a first hinge axis D1 relative to the first housing 110 and cradled at a set angle of rotation.

The portable electronic device 100 may have the shape of a bar.

The operation of the portable electronic device according to the first exemplary embodiment of the present invention, which is constructed as mentioned above, will now be described in more detail with reference to FIG. 1 and FIG. 2.

As shown in FIG. 1, a portion of the first housing 110 is rotatably connected to a portion of the second housing 120 by the connection unit 130.

When the user wants to watch TV programs or moving pictures, the second housing 120 is rotated about the first hinge axis D1 of the connection unit 130 and then cradled at a set angle of rotation, as shown in FIG. 2.

After the second housing 120 is rotated relative to the first housing 110 and cradled stably in an inclined state, the user may watch moving pictures via the display device 121 of the second housing 120.

If the user wants to use the portable electronic device 100 in a communication mode, the second housing 120 is rotated about the first hinge axis D1 and positioned to be planar with the first housing 110, as shown in FIG. 1.

The user then can use the portable electronic device 100 in the communication mode.

A portable electronic device according to a second exemplary embodiment of the present invention will now be described.

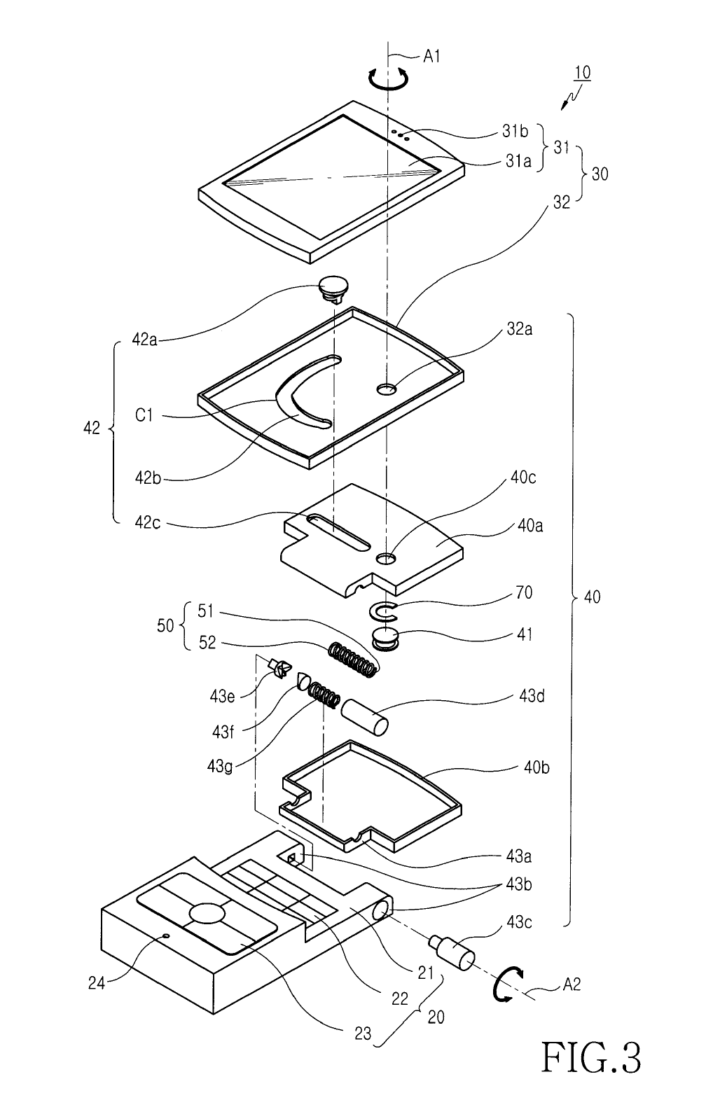

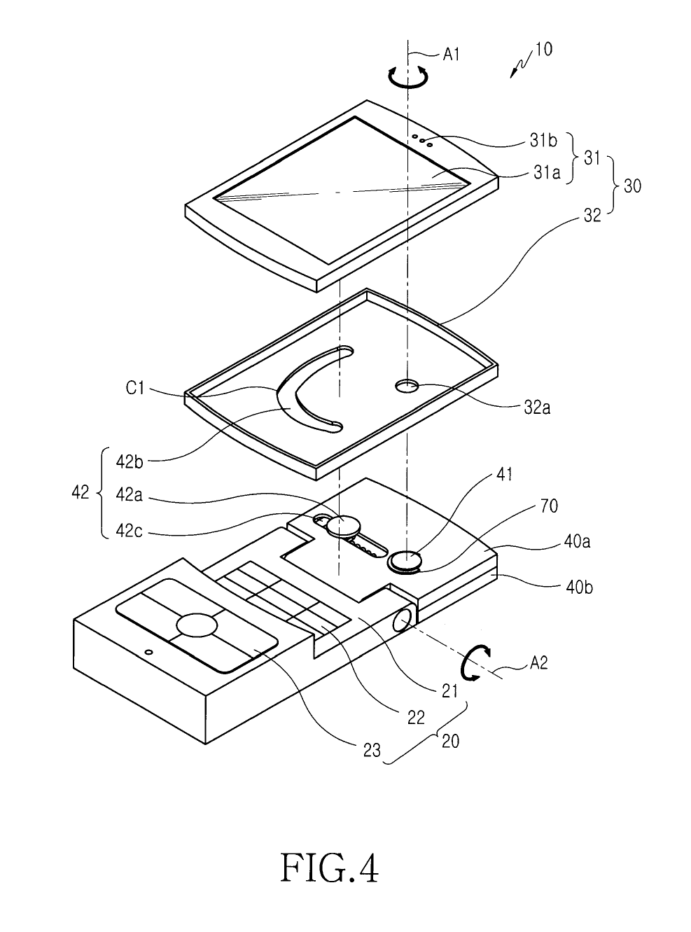

As shown in FIG. 3 and FIG. 4, the portable electronic device 10 includes a first housing 20, a second housing 30, and a connection unit 40. A portion of the upper surface of the first housing 20 is depressed to provide a mounting recess 21, which faces the second housing 30. The first housing 20 has a first keypad 22, a second keypad 23, and a microphone device 24. The second housing 30 has a display device 31a and a speaker device 31b. The second housing 30 is positioned on the upper surface of the first housing 20 and is adapted to rotate about a first hinge axis A1, which is arranged away from the inner center of the second housing 30, so that the display device 31a is positioned at the center of the first housing 20. The display device 31a may then be rotated about a second hinge axis A2, which is perpendicular to the first hinge axis A1, and cradled at an angle. The connection unit 40 provides the first and second hinge axes A1 and A2 and connects the first and second housings 20 and 30 so that the second housing 30 can rotate about the first and second hinge axes A1 and A2.

As shown in FIG. 4, the first keypad 22 includes an array of keys positioned on the mounting recess 21 so that they are exposed/covered as the second housing 30 rotates about the first hinge axis A1. The second keypad 23 includes an array of keys that are always exposed.

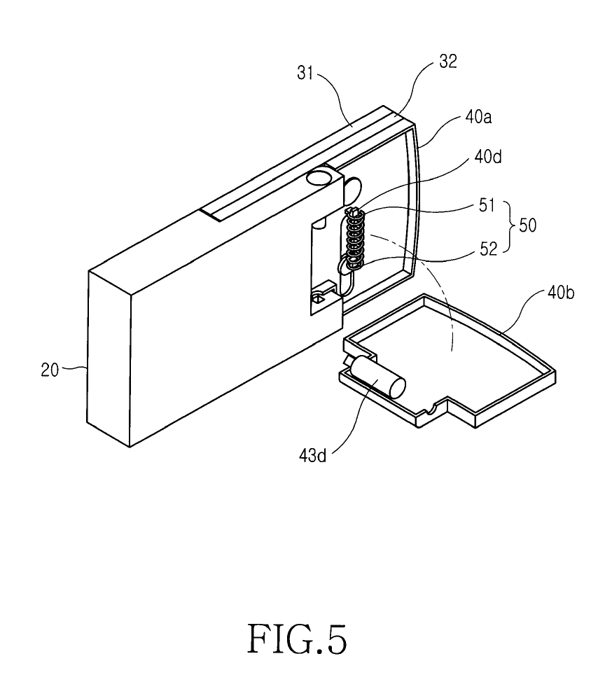

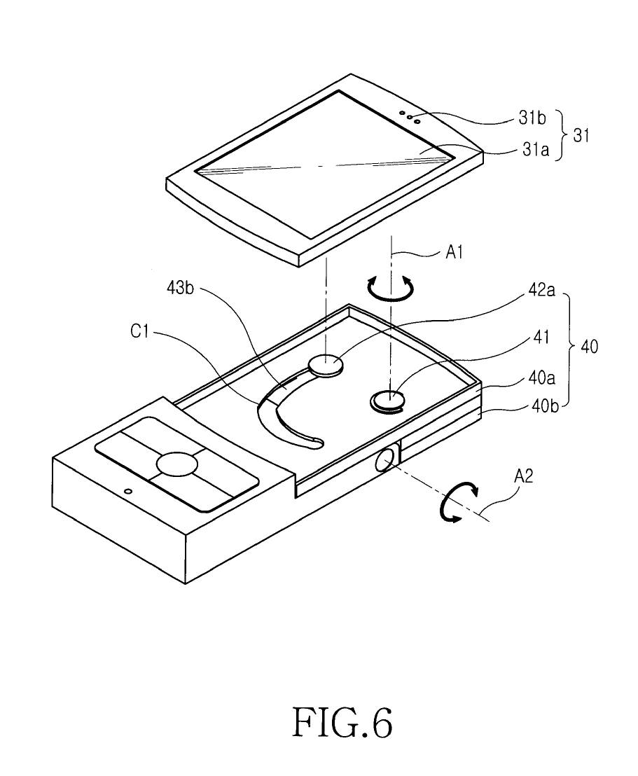

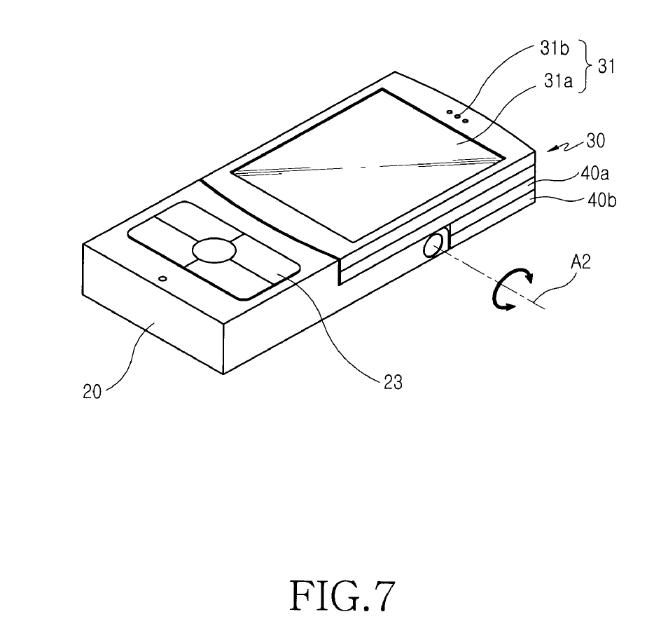

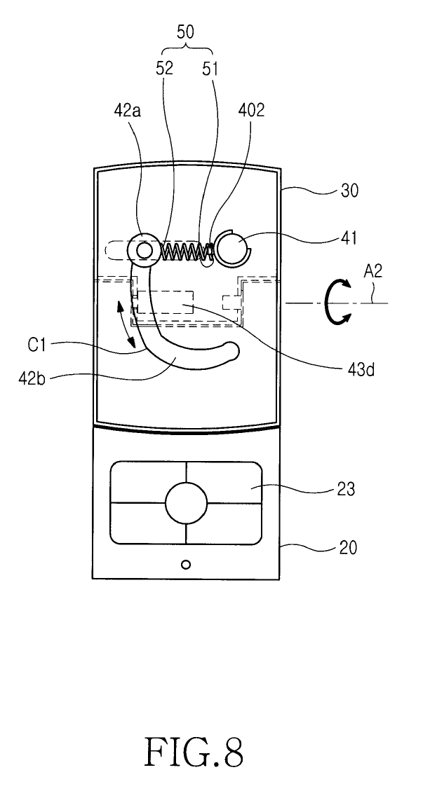

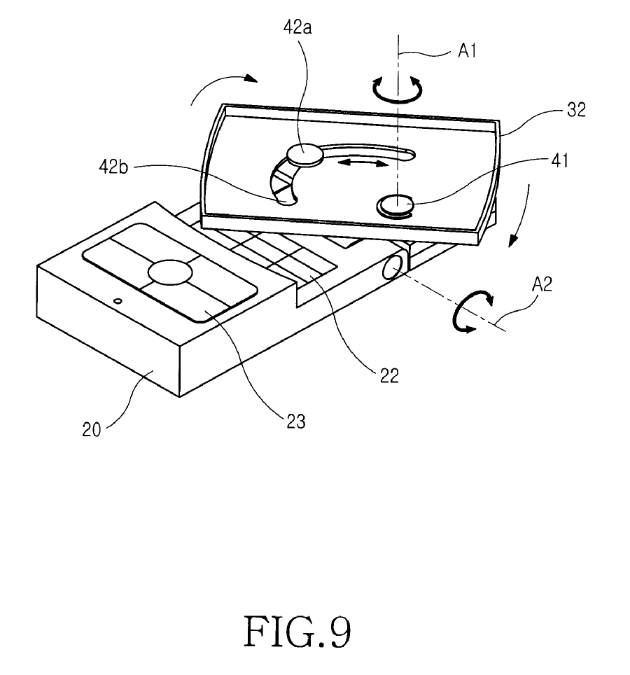

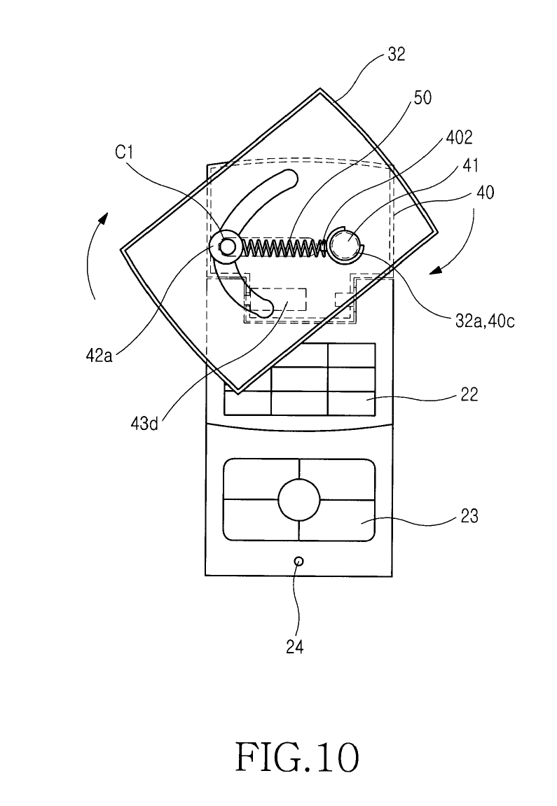

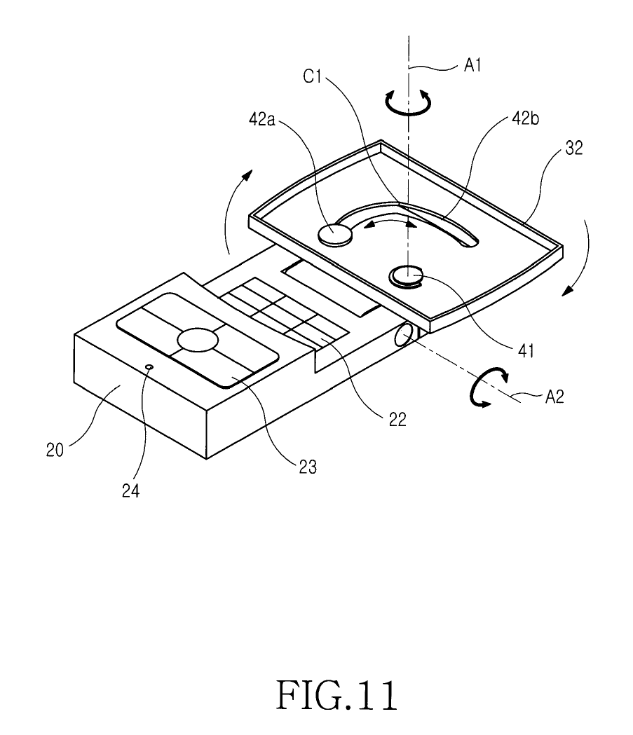

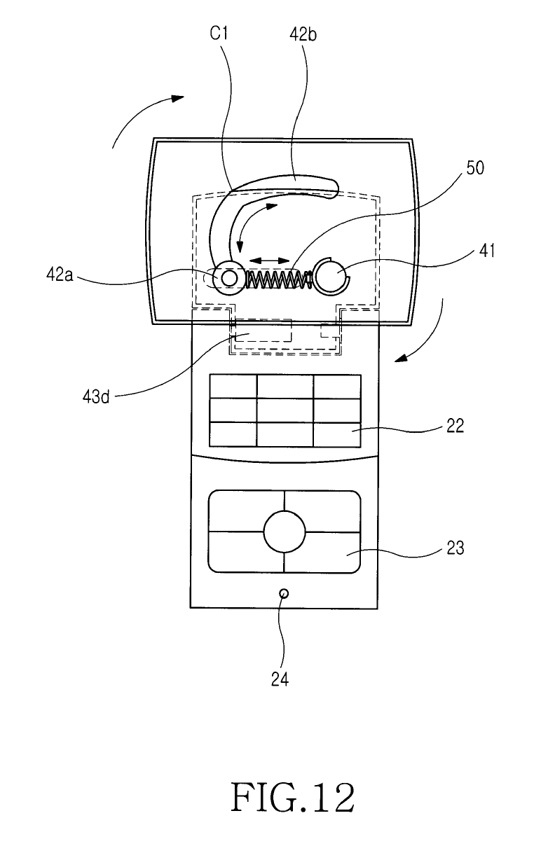

As shown in FIG. 3, FIG. 4, FIG. 5, FIG. 6, FIG. 7, FIG. 8, FIG. 9, FIG. 10, FIG. 11, and FIG. 12, the second housing 30 includes first and second cases 31 and 32. The first case 32 has a display device 31a and a speaker device 31b. The second case 32 has a first guide hole 42b and a hinge hole 32a formed therein (described later). The connection unit 40 includes a hinge connection device, a guide movement unit 42, and a cradling hinge device 43. The hinge connection device is positioned between the second housing 30 and the connection unit 40 and extends through hinge holes 32a and 40c, which are arranged away from the center of the second housing 30 and the connection unit 40, so that the second housing 30 can rotate about the first hinge axis A1 while facing the connection unit 40. The guide movement unit 42 is positioned between the second housing 30 and the connection unit 40 so that, when the second housing 30 rotates about the first hinge axis A1, the rotation and linear movement of the second housing 30 is guided. The cradling hinge device 43 includes a pair of side hinge arms 43a positioned on the first housing 20 and a center hinge arm 43b positioned on the connection unit 40 and connected to the side hinge arms 43a while being able to rotate about the second hinge axis A2 so that the second housing 30 and the connection unit 40 can be cradled at an angle relative to the first housing 20.

As shown in FIG. 3, the hinge connection device may be a rotation bush 41 coupled to the hinge hole 32a of the second housing 30 and the hinge hole 40c of the connection unit 40 while extending through them. An O-ring 70 may be fastened to the rotation bush 41.

As shown in FIG. 3 and FIG. 5, the connection unit 40 includes first and second cases 40a and 40b.

As shown in FIG. 3, FIG. 7, FIG. 8, FIG. 9, FIG. 10, FIG. 11, and FIG. 12, the guide movement unit 42 includes a guide roller unit 42a, a first guide hole 42b, and a second guide hole 42c. The guide roller unit 42a is positioned on the second housing 30 and coupled to the first and second guide holes 42b and 42c, which will be described below, while extending through them so that, when the second housing 30 is rotated about the first hinge axis A1, the guide roller unit 42a is guided along the first guide hole 42b while moving linearly along the second guide hole 42c. The first guide hole 42b is formed in the second case 32 of the second housing 30 and coupled to the guide roller unit 42a so that, when the second housing 30 is rotated about the first hinge axis A1, the first guide hole 42b guides the movement of the guide roller unit 42a. The second guide hole 42c is formed in the first case 40a of the connection unit 40 so as to correspond to the first guide hole 42b and is coupled to the guide roller unit 42a so that the guide roller unit 42a is guided along the first guide hole 42b while moving linearly.

As shown in FIG. 3, FIG. 5, FIG. 8, FIG. 10, and FIG. 12, the connection unit 40 is provided with an elastic body 50 to generate compressive/tensile force when the second housing 30 rotates about the first hinge axis A1 and when the guide roller unit 42a moves linearly so that the second housing 30 can rotate to a specific angle of rotation. The elastic body 50 includes a coil spring, one end 51 of which is disposed on a spring fixing unit 40d disposed inside the connection unit 40, and the other end 52 of which is fastened to a fixing protrusion 402 formed on the guide roller unit 42a so as to provide compressive/tensile force when the guide roller unit 42a moves linearly.

As shown in FIG. 3 and FIG. 8, the first guide hole 42b may have a curved shape and include an inflection point C1.

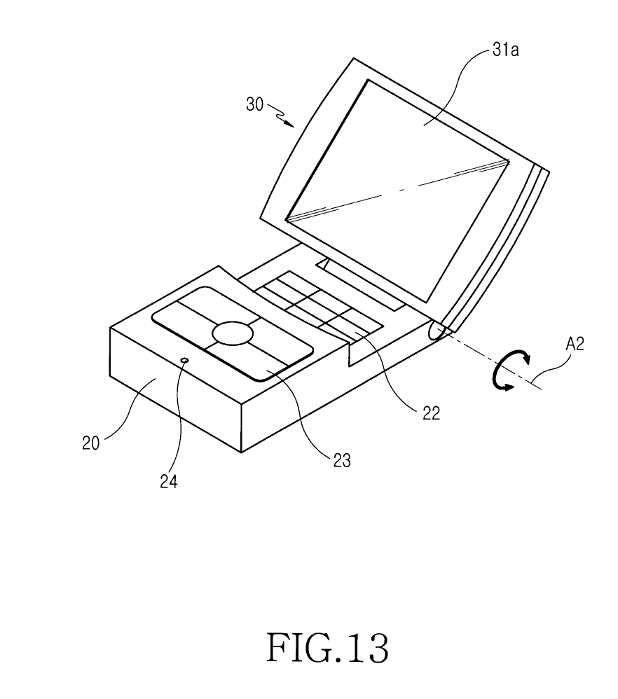

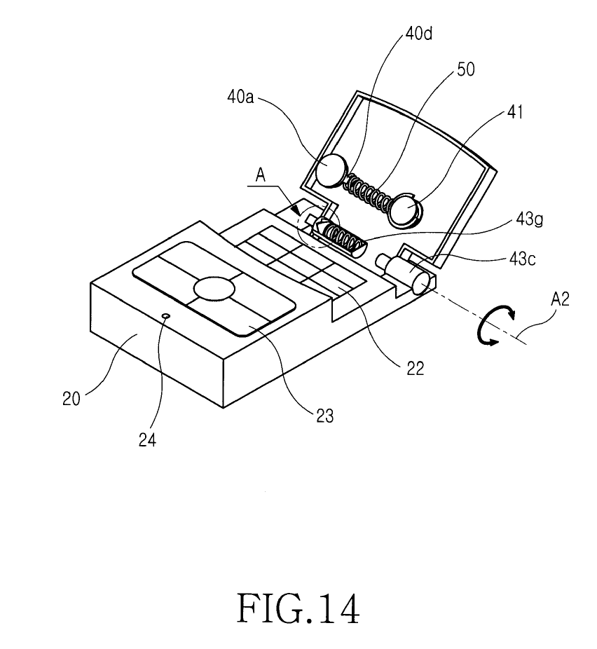

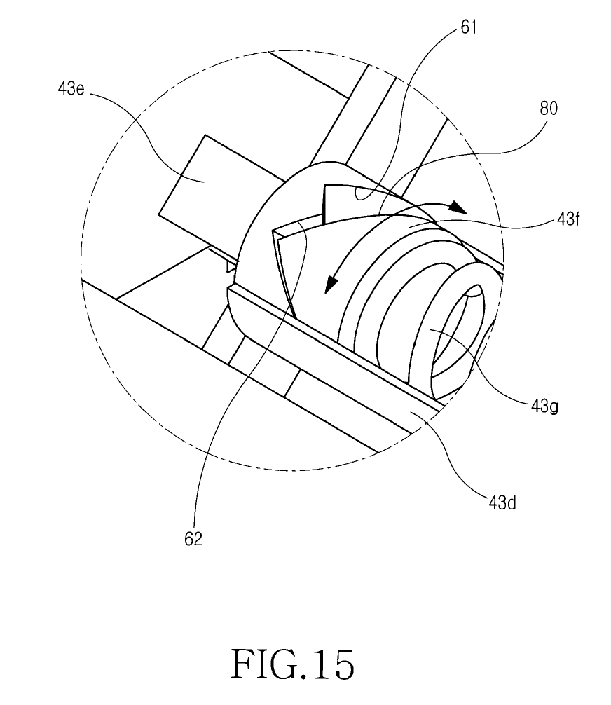

As shown in FIG. 3, FIG. 13, FIG. 14, and FIG. 15, the cradling hinge device 43 includes a pair of side hinge arms 43a, a center hinge arm 43b, a hinge rod 43c, a cam housing 43d, a hinge cam 43e, a hinge shaft 43f, and a coil spring 43g. The side hinge arms 43a are disposed on an end of the first housing 20 and are rotatably coupled to the center hinge arm 43b. The center hinge arm 43b is disposed on an end of the connection unit 40 and is rotatably coupled to the side hinge arms 43a. The hinge rod 43c is positioned in one of the side hinge arms 43a and rotatably couples the hinge arms 43a and 43b. The cam housing 43d is positioned in the center hinge arm 43b and is successively coupled to the hinge arm 43e, the hinge shaft 43f, and the coil spring 43g. A surface of the hinge cam 43e is coupled to the other side hinge arm 43a so that it can engage with/disengage from a crest 80 of the hinge shaft 43f, which will be described below.

As shown in FIG. 15, the hinge cam 43e has first and second troughs 61 and 62 having curved surfaces on another surface thereof. The first and second troughs 61 and 62 are adapted to engage with/disengage from a crest 80 so that the second housing 30 and the connection unit 40 can be cradled at an angle. The hinge shaft 43f includes the crest 80 having a curved surface facing the first and second troughs 61 and 62 of the hinge cam 43e. The hinge shaft 43f is adapted to move linearly inside the cam housing 43d so that, when the second housing 30 rotates about the second housing A2, the crest 80 engages with/disengages from the first and second troughs 61 and 62.

As shown in FIG. 14 and FIG. 15, the coil spring 43g is positioned in the cam housing 43d and compresses the hinge shaft 43f so that the crest 80 can engage with/disengage from the curved surfaces of the first and second troughs 61 and 62.

The first trough 62 engages with the crest 80 and maintains the second housing 30 and the connection unit 40 in a pre-cradling condition.

As shown in FIG. 13, FIG. 14, and FIG. 15, the crest 80 disengages from the first trough 61 and then engages with the second trough 62. In this condition, the second housing 30 and the connection unit 40 are cradled at an angle.

The display device 31a includes a touch screen.

The operation of the portable electronic device according to the second exemplary embodiment of the present invention, which is constructed as mentioned above, will now be described in more detail with reference to FIG. 3, FIG. 4, FIG. 5, FIG. 6, FIG. 7, FIG. 8, FIG. 9, FIG. 10, FIG. 1, FIG. 12, FIG. 13, FIG. 14, and FIG. 15.

As shown in FIG. 3, FIG. 4, FIG. 5, and FIG. 6, the portable electronic device 10 includes a first housing 20 having first and second keypads 22 and 23, a second housing 30 having a display device 31a, and a connection unit 40 having first and second cases 40a and 40b. The connection unit 40 includes a hinge connection device, a guide movement unit 42, and a cradling hinge device 43. The hinge connection device may include a rotation bush 41, which is coupled to a hinge hole 32a formed in the second case 32 of the second housing 30 while extending through it. The rotation bush 41 is then rotatably coupled to a hinge hole 40c in the first case 40a of the connection unit 40 while extending through it.

As shown in FIG. 3 and FIG. 10, the hinge holes 32a and 40c are in the second housing 30 and the connection unit 40, respectively. The first case 31 of the second housing 30 is coupled to the second case 32 of the second housing 30. A cam housing 43d is disposed in the connection unit 40, which couples the first and second cases 40a and 40b to each other. A center hinge arm 43b disposed on an end of the connection unit 40 is rotatably coupled to a pair of side hinge arms 43a disposed on an end of the first housing 20. A hinge rod 43c is coupled to one of the side hinge arms 43a to rotatably support the center hinge arm 43b.

As shown in FIG. 3, FIG. 13, FIG. 14, and FIG. 15, the center hinge arm 43b is provided with a cam housing 43d, and a hinge cam 43e is disposed in the cam housing 43d. A surface of the hinge cam 43e is coupled to the side hinge arm 43a, and first and second troughs 61 and 62 are on another surface of the hinge cam 43e. The first and second troughs 61 and 62 face a crest 80 on the front surface of the hinge shaft 43f. A coil spring 43g is disposed on the rear surface of the hinge shaft 43f and compresses the crest 80 against the first and second troughs 61 and 62.

As shown in FIG. 7, FIG. 8, FIG. 9, and FIG. 10, the user rotates the second housing 30 about the first hinge axis A1 to watch TV programs or moving pictures using the first guide hole 42b in the second case 32 of the second housing 30. The guide roller unit 42a of the guide movement unit 42 moves along the first guide hole 42b, which has a curved shape, when the second housing 30 rotates.

As shown in FIG. 9, FIG. 10, FIG. 11, and FIG. 12, the guide roller unit 42a is guided along the curve of the first guide hole 42b while moving linearly along the second guide hole 42c. Thus, the guide roller unit 42a linearly moves away from the first hinge axis A1. When the guide roller unit 42a is positioned at the inflection point C1 of the first guide hole 42b, the elastic body 50 fastened to the guide roller unit 42a exerts tensile force. After the guide roller 42a passes the inflection point C1, the elastic body 50 exerts compressive force that pulls the guide roller unit 42a towards the first hinge axis A1 while moving it linearly.

As shown in FIG. 11 and FIG. 12, the guide roller unit 42a moves linearly along the second guide hole 42c. The guide roller unit 42a is pulled by the compressive force from the elastic body 50 and is guided linearly along the first guide hole 42b.

As shown in FIG. 11 and FIG. 12, the second housing 30 is rotated and the display device 31a is positioned at the center of the first housing 20.

As shown in FIG. 13, FIG. 14, and FIG. 15, the second housing 30 and the connection unit 40 are cradled at an angle about the second hinge axis A2. When the connection unit 40 is rotated and cradled at an angle, the hinge shaft 43f and its crest 80 rotate together. Then, the crest 80 disengages from the first trough 61 of the hinge cam and engages with the second trough 62. The rotation of the hinge shaft 43f, which has been compressed by the coil spring 43g, is followed by a linear movement of the crest 80 of the hinge shaft 43f. Then, the crest 80 disengages from the first trough 61 and engages with the second trough 62 again. The coil spring 43g compresses the hinge shaft 43f again.

As shown in FIG. 13, the user can watch TV programs or moving pictures when the display device 31a of the second housing 30 is cradled at an angle. When the second housing 30 is rotated about the first hinge axis A1, the first keypad 22 on the first housing 20 is exposed.

When the user wants to return the second housing 30 and the connection unit 40 to their original positions, the second housing 30 is rotated about the second hinge axis A2 and positioned along the same line as the first housing, as shown in FIG. 11 and FIG. 12.

As shown in FIG. 7, FIG. 8, FIG. 9, and FIG. 10, the guide roller unit 42a moves linearly along the second guide hole 42c while also moving along the first guide hole 42b, thereby rotating the second housing 30. When the guide roller unit 42a is positioned at the inflection point C1 of the first guide hole 42b, the elastic body 50 exerts tensile force. After the guide roller 42a passes the inflection point C1, the elastic body 50 exerts compressive force which pulls the guide roller unit 42a and moves it linearly so that it is guided along the first guide hole 42b and rotates the second housing 30.

The rear surface of the second housing 30 faces the upper surface of the first housing 20 and the upper surface of the connection unit 40.

The second housing 30 covers the first keypad 22.

The display device 31a of the second housing 30 includes a touch screen.

As mentioned above, the portable electronic device according to exemplary embodiments of the present invention has a display unit that is mounted in a housing and adapted to rotate so as to be cradled at an angle so that a user may efficiently use the device and conveniently watch TV programs and moving pictures.

The present invention is applicable to all types of portable electronic devices, including bar-type, flip-type, and folder-type devices.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents

What is claimed is:

1. A bar-type portable electronic device, comprising:
a first housing having a keypad;
a second housing having a display device; and
a connection unit to rotatably couple the first housing and the second housing so that the second housing can be rotated about a first hinge axis relative to the first housing and then fixed at a specific angle of rotation.

2. The portable electronic device of claim 1, wherein the display device is adapted to rotate in a transverse direction.

3. A portable electronic device, comprising:
a first housing having a keypad;
a second housing having a display device, the second housing being adapted to rotate about a first hinge axis so that the display device is positioned at the center of the first housing and then rotated about a second hinge axis extending in a direction perpendicular to the first hinge axis to be cradled at an angle; and
a connection unit to provide the first hinge axis and the second hinge axis and connect the first housing and the second housing so the second housing can rotate about the first hinge axis and the second hinge axis.

4. The portable electronic device of claim 3, wherein the first housing has a mounting recess that faces the second housing.

5. The portable electronic device of claim 4, wherein the keypad comprises:
a first keypad positioned inside the mounting recess so as to be exposed when the second housing rotates about the first hinge axis in a first direction and covered when the second housing rotates about the first hinge axis in a second direction,
a second keypad that is always exposed, and
a microphone device being positioned adjacent to the second keypad.

6. The portable electronic device of claim 3, wherein the first hinge axis is arranged away from the center of the second housing.

7. The portable electronic device of claim 3, wherein the connection unit comprises:
a hinge connection device coupled to hinge holes in the second housing and the connection unit, the hinge connection device being arranged away from the centers of the second housing and the connection unit while extending through the hinge holes so that the second housing can rotate about the first hinge axis while facing the connection unit;
a guide movement unit positioned between the second housing and the connection unit so that the second housing is guided to rotate and move linearly when the second housing rotates about the first hinge axis; and
a cradling hinge device having a pair of side hinge arms and a center hinge arm positioned on the first housing and the connection unit, respectively, and coupled so that respective hinge arms can rotate about the second hinge axis and that the second housing and the connection unit can be cradled at an angle relative to the first housing.

8. The portable electronic device of claim 7, wherein the hinge connection device comprises a rotation bush.

9. The portable electronic device of claim 7, wherein the guide movement unit comprises:
a guide roller unit positioned inside the second housing while being able to move;
a first guide hole in the second housing and coupled to the guide roller unit with the guide roller unit extending through the first guide hole so that the first guide hole guides a linear movement of the guide roller unit when the second housing rotates about the first hinge axis; and
a second guide hole in a first case of the connection unit, the second guide hole being positioned to correspond to the first guide hole and coupled to the guide roller unit, the guide roller unit extending through the second guide hole so that the guide roller unit moves linearly along the second guide hole.

10. The portable electronic device of claim 7, wherein the connection unit incorporates an elastic body to generate compressive/tensile force when the second housing rotates about the first hinge axis and when the guide roller unit moves linearly so that the second housing is rotated, and
wherein the elastic body comprises a coil spring, a first portion of the coil spring being disposed on a spring fixing unit disposed inside the connection unit, and a second portion of the coil spring being fastened to a fixing protrusion disposed on the guide roller unit so as to provide compressive/tensile force when the guide roller unit moves linearly.

11. The portable electronic device of claim 9, wherein the first guide hole has a curved shape and an inflection point so that when the second housing rotates, the guide roller unit moves away from the first hinge axis along a curve of the first guide hole,
wherein the elastic body exerts tensile force when the guide roller unit is positioned at the inflection point of the first guide hole, and
wherein the elastic body exerts compressive force when the guide roller unit moves away from the inflection point so that the guide roller unit moves towards the first hinge axis and the second housing is rotated.

12. The portable electronic device of claim 7, wherein the cradling hinge device comprises:
a pair of side hinge arms disposed on an end of the first housing;
a center hinge arm disposed on an end of the connection unit;
a hinge rod provided on the side hinge arms to rotatably couple respective hinge arms;
a cam housing provided inside the center hinge arm;
a hinge cam provided inside the cam housing, an end of the hinge cam being coupled to the side hinge arms, a first trough and a second trough on a surface of the hinge cam;
a hinge shaft arranged to move linearly inside the cam housing, the hinge shaft having a crest positioned to face the first trough and the second trough of the hinge cam and adapted to rotate when the second housing rotates about the second hinge axis and engage with/disengage from the first trough and the second trough; and
a coil spring to compress the hinge shaft so that the crest can engage with/disengage from curved surfaces of the first trough and the second trough.

13. The portable electronic device of claim 12, wherein the crest is adapted to engage with the first trough and maintain the second housing and the connection unit in a pre-cradling condition and,
wherein the crest disengages from the first trough and engages with the second trough so that the second housing and the connection unit are maintained in a cradling condition at an angle.

14. The portable electronic device of claim 3, wherein the display device comprises a touch screen.
